(19) United States
(12) Patent Application Publication
(10) Pub. No.: US 2020/0272364 A1
(43) Pub. Date: Aug. 27, 2020

(54) DYNAMIC BLOCK-LEVEL COMPRESSION UTILIZATION

(71) Applicant: International Business Machines Corporation, Armonk, NY (US)

(72) Inventors: Ning Zhao, Shanghai (CN); Dan Liu, Shanghai (CN); Ting Wang, Shanghai (CN); Si Cong Zhou, Shanghai (CN)

(73) Assignee: International Business Machines Corporation, Armonk, NY (US)

(21) Appl. No.: 16/286,802

(22) Filed: Feb. 27, 2019

(51) Int. Cl. G06F 3/06; G06F 13/16; H03M 7/30

(52) U.S. Cl. CPC G06F 3/0661; G06F 3/0608; H03M 7/6011; G06F 3/0673; G06F 13/1668; G06F 3/064

(57) ABSTRACT

A method for more efficiently utilizing data compression in block-level storage systems is disclosed. In one embodiment, such a method includes receiving, by a storage system, I/O operations from a host system. The storage system determines, at a selected interval, a compression rate of data associated with the I/O operations. Using the compression rate determined at the selected interval, the storage system updates an average compression rate. The storage system then determines whether the average compression rate is above a threshold. If the average compression rate is above the threshold, the storage system compresses data associated with I/O operations from the host system. If the average compression rate is not above the threshold, the storage system does not compress data associated with I/O operations from the host system. A corresponding system and computer program product are also disclosed.

### BACKGROUND

### Field of the Invention

This invention relates to systems and methods for more efficiently utilizing data compression in block-level storage systems.

### Background of the Invention

Although the cost per GB of storage has been steadily declining, the demand for additional storage capacity has nevertheless been growing at a faster rate. For this reason, various techniques have been developed to increase the effective storage capacity of backend storage drives such as disk drives. One way to increase effective storage capacity is to use data compression. Today, data compression is most commonly applied at the file level. This is because compressing data at the file level typically enables compressing larger objects. Compressing data at the file level also enables access to data semantics and statistics maintained by a file system.

Because of its ability to increase effective storage capacity, more and more users are utilizing data compression to store data on backend storage drives. However, block-level storage systems, as opposed to file-level storage systems, are typically not aware of the type of data that is being stored by a host system. Thus, these storage systems typically cannot make decisions as to whether to compress or not compress data. As a result, users who have knowledge of data types and applications running on host systems typically make the decisions whether to compress or not compress data.

In some cases, users may choose to use data compression even though the data they are processing is not suitable for compression. This may be because certain types of data (e.g., image data, video data, sequential I/O, etc.) cannot be significantly compressed. In some extreme cases, compressing the data may actually cause the data size to increase. In such cases, host performance may be significantly impacted since processing resources may be dedicated to compressing/decompressing data without any significant gains in terms of increasing effective storage capacity.

In view of the foregoing, what are needed are systems and methods to more effectively determine when to compress or not compress data. Ideally, such systems and methods will enable block-level storage systems to intelligently decide when to compress or not compress data.

### SUMMARY

The invention has been developed in response to the present state of the art and, in particular, in response to the problems and needs in the art that have not yet been fully solved by currently available systems and methods. Accordingly, systems and methods in accordance with the invention have been developed to more efficiently utilize data compression in block-level storage systems. The features and advantages of the invention will become more fully apparent from the following description and appended claims, or may be learned by practice of the invention as set forth hereinafter.

Consistent with the foregoing, a method for more efficiently utilizing data compression in block-level storage systems is disclosed. In one embodiment, such a method includes receiving, by a storage system, I/O operations from a host system. The storage system determines, at a selected interval, a compression rate of data associated with the I/O operations. Using the compression rate determined at the selected interval, the storage system updates an average compression rate. The storage system then determines whether the average compression rate is above a threshold. If the average compression rate is above the threshold, the storage system compresses data associated with I/O operations from the host system. If the average compression rate is not above the threshold, the storage system does not compress data associated with I/O operations from the host system.

A corresponding system and computer program product are also disclosed and claimed herein.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a high-level block diagram showing one example of a network environment in which systems and methods in accordance with the invention may be implemented;

FIG. 2 is a high-level block diagram showing one embodiment of a storage system for use in the network environment of FIG. 1;

FIG. 3 shows a dynamic compression module that dynamically enables/disables data compression within a storage system such as that illustrated in FIG. 2;

FIGS. 4 and 5 show a technique for calculating an average compression rate for data received by a storage system; and

FIG. 6 is a flow diagram showing one embodiment of a method for dynamically enabling/disabling data compression within a storage system.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

The present invention may be embodied as a system, method, and/or computer program product. The computer program product may include a computer readable storage medium (or media) having computer readable program instructions thereon for causing a processor to carry out aspects of the present invention.

The computer readable storage medium may be a tangible device that can retain and store instructions for use by an instruction execution device. The computer readable storage medium may be, for example, but is not limited to, an electronic storage system, a magnetic storage system, an optical storage system, an electromagnetic storage system, a semiconductor storage system, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage system via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages.

The computer readable program instructions may execute entirely on a user's computer, partly on a user's computer, as a stand-alone software package, partly on a user's computer and partly on a remote computer, or entirely on a remote computer or server. In the latter scenario, a remote computer may be connected to a user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention may be described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, may be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

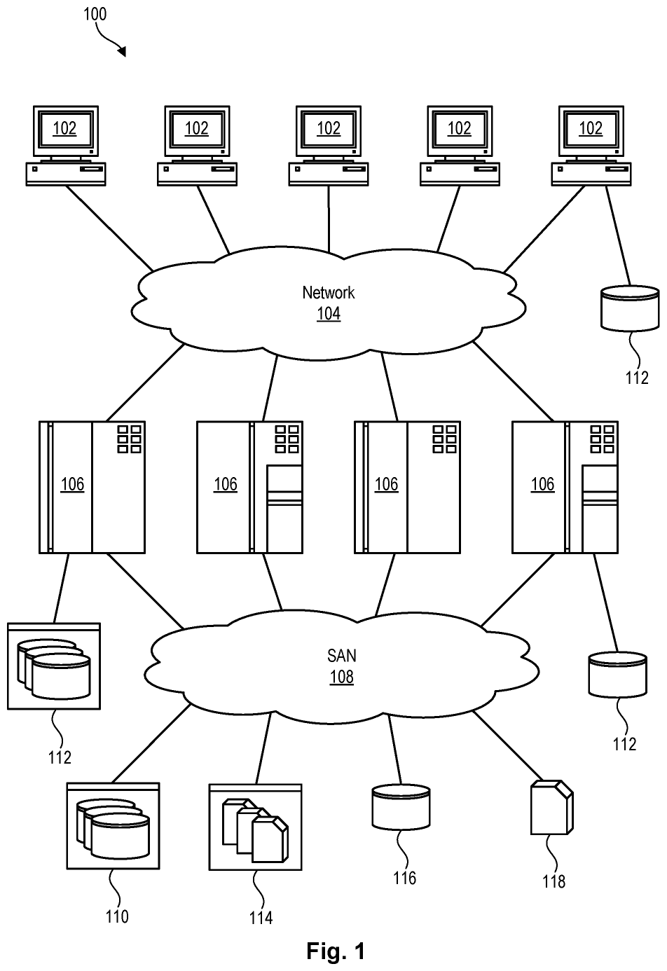

Referring to FIG. 1, one example of a network environment 100 is illustrated. The network environment 100 is presented to show one example of an environment where systems and methods in accordance with the invention may be implemented. The network environment 100 is presented by way of example and not limitation. Indeed, the systems and methods disclosed herein may be applicable to a wide variety of different network environments in addition to the network environment 100 shown.

As shown, the network environment 100 includes one or more computers 102, 106 interconnected by a network 104. The network 104 may include, for example, a local-area-network (LAN) 104, a wide-area-network (WAN) 104, the Internet 104, an intranet 104, or the like. In certain embodiments, the computers 102, 106 may include both client computers 102 and server computers 106 (also referred to herein as “hosts” 106 or “host systems” 106). In general, the client computers 102 initiate communication sessions, whereas the server computers 106 wait for and respond to requests from the client computers 102. In certain embodiments, the computers 102 and/or servers 106 may connect to one or more internal or external direct-attached storage systems 112 (e.g., arrays of hard-storage drives, solid-state drives, tape drives, etc.). These computers 102, 106 and direct-attached storage systems 112 may communicate using protocols such as ATA, SATA, SCSI, SAS, Fibre Channel, or the like.

The network environment 100 may, in certain embodiments, include a storage network 108 behind the servers 106, such as a storage-area-network (SAN) 108 or a LAN 108 (e.g., when using network-attached storage). This network 108 may connect the servers 106 to one or more storage systems, such as arrays 110 of hard-disk drives or solid-state drives, tape libraries 114, individual hard-disk drives 116 or solid-state drives 116, tape drives 118, CD-ROM libraries, or the like. To access a storage system 110, 114, 116, 118, a host system 106 may communicate over physical connections from one or more ports on the host 106 to one or more ports on the storage system 110, 114, 116, 118. A connection may be through a switch, fabric, direct connection, or the like. In certain embodiments, the servers 106 and storage systems 110, 114, 116, 118 may communicate using a networking standard such as Fibre Channel (FC) or iSCSI.

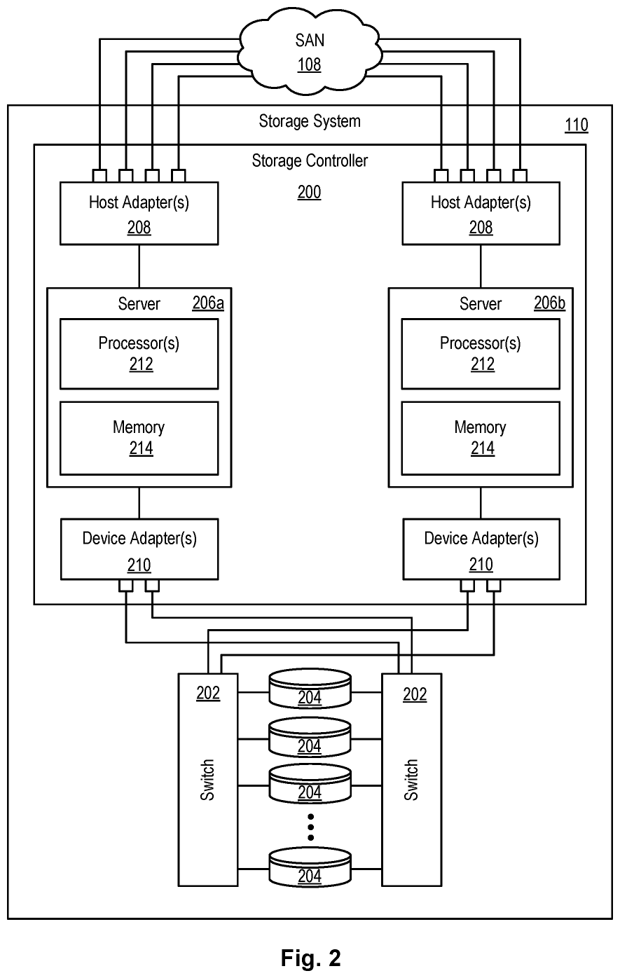

Referring to FIG. 2, one example of a storage system 110 containing an array of hard-disk drives 204 and/or solid-state drives 204 is illustrated. The internal components of the storage system 110 are shown since the data compression techniques disclosed herein may, in certain embodiments, be implemented within such a storage system 110. As shown, the storage system 110 includes a storage controller 200, one or more switches 202, and one or more storage drives 204, such as hard-disk drives 204 and/or solid-state drives 204 (e.g., flash-memory-based drives 204). The storage controller 200 may enable one or more hosts 106 (e.g., open system and/or mainframe servers 106 running operating systems such z/OS, zVM, or the like) to access data in the one or more storage drives 204.

In selected embodiments, the storage controller 200 includes one or more servers 206. The storage controller 200 may also include host adapters 208 and device adapters 210 to connect the storage controller 200 to host devices 106 and storage drives 204, respectively. Multiple servers 206a, 206b may provide redundancy to ensure that data is always available to connected hosts 106. Thus, when one server 206a fails, the other server 206b may pick up the I/O load of the failed server 206a to ensure that I/O is able to continue between the hosts 106 and the storage drives 204. This process may be referred to as a “failover.”

In selected embodiments, each server 206 may include one or more processors 212 and memory 214. The memory 214 may include volatile memory (e.g., RAM) as well as non-volatile memory (e.g., ROM, EPROM, EEPROM, hard disks, flash memory, etc.). The volatile and non-volatile memory may, in certain embodiments, store software modules that run on the processor(s) 212 and are used to access data in the storage drives 204. The servers 206 may host at least one instance of these software modules. These software modules may manage all read and write requests to logical volumes in the storage drives 204.

One example of a storage system 110 having an architecture similar to that illustrated in FIG. 2 is the IBM DS8000™ enterprise storage system. The DS8000™ is a high-performance, high-capacity storage controller providing disk and solid-state storage that is designed to support continuous operations. Nevertheless, the techniques disclosed herein are not limited to the IBM DS8000™ enterprise storage system 110, but may be implemented in any comparable or analogous storage system 110, regardless of the manufacturer, product name, or components or component names associated with the system 110. Any storage system that could benefit from one or more embodiments of the invention is deemed to fall within the scope of the invention. Thus, the IBM DS8000™ is presented only by way of example and not limitation.

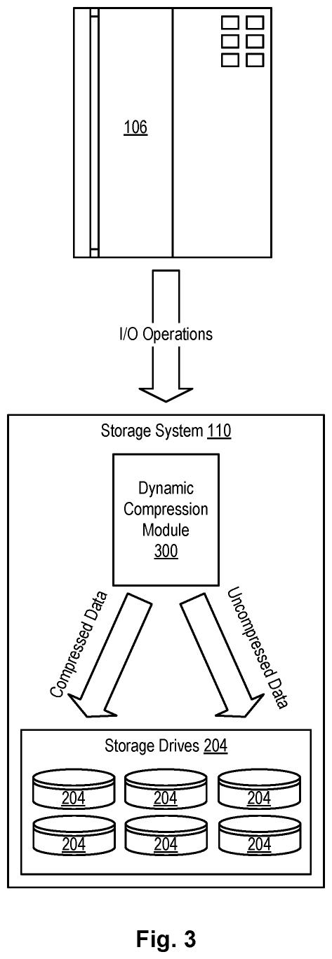

Referring to FIG. 3, as previously mentioned, because of its ability to increase effective storage capacity, more and more users are utilizing data compression to store data on backend storage drives 204. However, block-level storage systems 110, as opposed to file-level storage systems, are typically not aware of the type of data that is being stored by a host system 106. Thus, these storage systems 110 typically cannot make a decision as to whether it would be effective to compress data that is stored thereon. As a result, users who have knowledge of data types and applications running on host systems 106 typically make the decisions as to whether to compress or not compress data.

In some cases, users may choose to compress data on a storage system 110 even though the data they are processing is not suitable for compression/decompression. This is because certain types of data (e.g., image data, video data, sequential I/O, etc.) does not compress significantly. In some extreme cases, compressing the data may actually cause the size of the data to increase. In such cases, host performance may be impacted since processing resources of the storage system 110 and/or host system 106 may be dedicated to compressing/decompressing data without any significant gains in terms of increasing effective storage capacity on the storage system 110.

Thus, systems and methods are needed to more effectively decide whether and when to compress or not compress data that is directed to a storage system 110. Ideally, such systems and methods will enable block-level storage systems 110 to intelligently decide when to compress or not compress data.

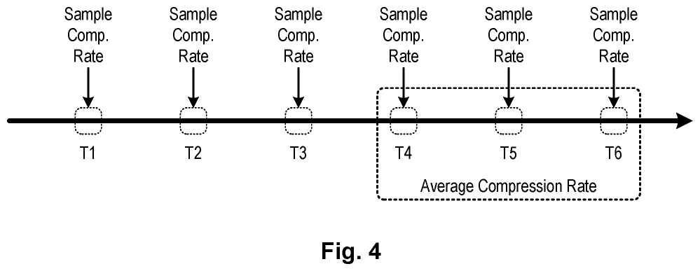

In certain embodiments in accordance with the invention, a dynamic compression module 300 may be implemented on a storage system 110 to decide whether and when to utilize data compression on the storage system 110. This dynamic compression module 300 may, in certain embodiments, be implemented within a block-level storage system 110 that has no awareness of the types of data that are being stored on the storage system 110. As shown, the dynamic compression module 300 may analyze data associated with I/O operations that are received by the storage system 110 and decide whether or not to compress the received data. In certain cases, the dynamic compression module 300 may decide to compress data received from a host system 106. In other cases, the dynamic compression module 300 may decide not to compress data received from a host system 106. The manner in which these decision are made will be discussed in association with FIGS. 4 through 6.

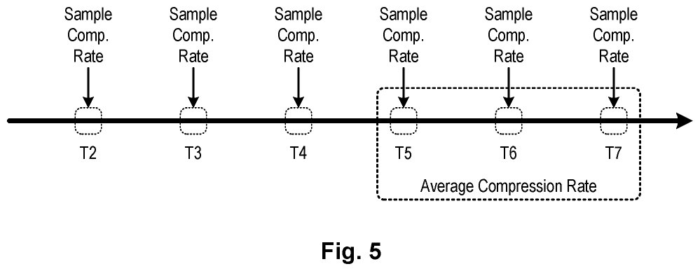

Referring to FIGS. 4 and 5, in certain embodiments in accordance with the invention, the dynamic compression module 300 may be configured to analyze data that is received from a host system 106. In certain cases, this data may be periodically sampled and compressed to determine a compression rate (e.g., a compression ratio) of the incoming data. For example, in certain embodiments, the data may be sampled and compressed at selected intervals, such as every five minutes. In such an example, each five minutes, the dynamic compression module 300 may compress the data associated with M I/O operations, where M is a selected number such as one hundred. The dynamic compression module 300 may then compute a compression rate associated with the M I/O operations. This compression rate may, in certain embodiments, be expressed as a ratio or percentage. For example, the compression rate may, in certain embodiments, be expressed as the size of the uncompressed data divided by the size of the data when compressed.

Once the dynamic compression module 300 calculates the compression rate, the dynamic compression module 300 may incorporate the compression rate into an average compression rate. In certain embodiments, the average compression rate is the average of the compression rates sampled and calculated for the last N intervals. For example, as shown in FIG. 4, the average compression rate is the average of the compression rates for the last three intervals (i.e., intervals T4 through T6). When the next compression rate is calculated for the next interval, the compression rate may be incorporated into the average compression rate and the oldest compression rate may fall out of the average compression rate, as shown in FIG. 5. In general, an average compression rate may be calculated to ensure that any outlier compression rate observed for a certain interval will not cause the dynamic compression module 300 to switch from compressing data to not compressing data, or vice versa.

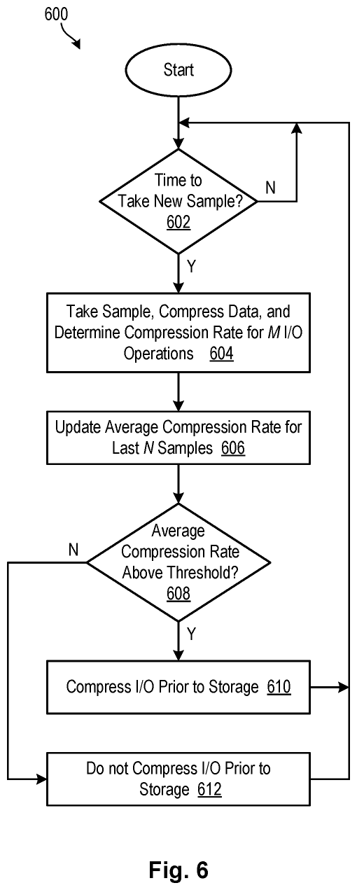

Referring to FIG. 6, one embodiment a method 600 for dynamically enabling/disabling data compression within a storage system 110 is illustrated. In certain embodiments, such a method 600 may be executed by the dynamic compression module 300 previously discussed.

As shown, the method 600 initially determines 602 whether it is time to take a new sample of I/O operations received from a host system 106. As previously, mentioned, samples may, in certain embodiments, be taken every interval, such as every five minutes. If its time to take a new sample, the method 600 takes 604 the sample and compresses 604 the data associated with the sample. For example, if the sample is one hundred I/O operations, the method 600 takes the one hundred I/O operations and compresses the data contained therein. In other embodiments, the sample includes I/O operations occurring over a selected amount of time (e.g., one second, half a second, etc.) as opposed to a certain number of I/O operations.

The method 600 then determines 604 the compression rate for the M I/O operations, assuming the sample includes a certain number of I/O operations. In certain embodiments, the compression rate is expressed as a ratio of the size of the compressed data to the size of the data when uncompressed.

The method 600 then updates 606 an average compression rate to include the compression rate calculated at step 604. As previously mentioned, in certain embodiments, the average compression rate is calculated by averaging the compression rates observed and calculated for the last N intervals. In certain embodiments, when the average compression rate is calculated, the most recently calculated compression rate is incorporated into the average compression rate and the oldest compression rate is removed. Sampling and calculating the compression rate at selected intervals and incorporating the measured compression rate into an average compression rate eliminates the need to continuously sample and compress data.

The method 600 then determines 608 whether the average compression rate is above a selected threshold. In general, the threshold may be selected to indicate a level at which data compression is turned on or off. For example, if data received from a host system 106 is shown to be moderately compressible, it may be advantageous to compress the data since this would yield significant gains in effective storage capacity. On the other hand, if data proves to be incompressible or minimally compressible, it may not be advantageous to compress the data. Doing such would require significant processing resources to compress/decompress data without yielding significant gains in effective storage capacity. The threshold may, in certain embodiments, be set at a level where the gains in effective storage capacity outweigh the costs in terms of processing resources needed to compress the data when it is stored on the backend storage drives 204, and decompress the data when it is retrieved from the backend storage drives 204. In other embodiments, the threshold is set based on a recommended compression rate for the storage system 110 or backend storage drives 204 on the storage system 110.

If, at step 608, the average compression rate is above the threshold, the method 600 may compress 610 data received from a host system 106 prior to storing it on backend storage drives 204. On the other hand, if the average compression rate is below the threshold, the method 600 may not compress 612 data received from the host system 106 prior to storing it on backend storage drives 204. Data that is compressed on the backend storage drives 204 will need to be decompressed when it is retrieved and/or utilized. The method 600 may then repeat by determining 602 whether it is time to take a new sample. In between the times the average compression rate is updated, the method 600 will either compress or not compress data received from a host system 106 depending on the outcome of the decision step 608.

The flowcharts and/or block diagrams in the Figures illustrate the architecture, functionality, and operation of possible implementations of systems, methods, and computer-usable media according to various embodiments of the present invention. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

1. A method for more efficiently utilizing data compression in block-level storage systems, the method comprising:
receiving, by a storage system, I/O operations from a host system;
determining, by the storage system at a selected interval, a compression rate of data associated with the I/O operations;
updating, by the storage system, an average compression rate with the compression rate determined at the selected interval;
determining, by the storage system, whether the average compression rate is above a threshold;
if the average compression rate is above the threshold, compressing data associated with the I/O operations; and
if the average compression rate is not above the threshold, not compressing data associated with the I/O operations.

2. The method of claim 1, wherein the average compression rate represents an average of the compression rate measured by the storage system for a last N intervals.

3. The method of claim 1, wherein the storage system is a block-level storage system.

4. The method of claim 1, wherein determining the compression rate comprises analyzing compressibility of data associated with the I/O operations for a selected period of time.

5. The method of claim 1, wherein determining the compression rate comprises analyzing compressibility of data associated with the I/O operations for a selected number of I/O operations.

6. The method of claim 1, wherein the threshold is based on a storage-recommended compression rate.

7. The method of claim 1, further comprising storing the data associated with the I/O operations on the storage system.

8. A computer program product for more efficiently utilizing data compression in block-level storage systems, the computer program product comprising a computer-readable medium having computer-usable program code embodied therein, the computer-usable program code configured to perform the following when executed by at least one processor:
receive, by a storage system, I/O operations from a host system;
determine, by the storage system at a selected interval, a compression rate of data associated with the I/O operations;
update, by the storage system, an average compression rate with the compression rate determined at the selected interval;
determine, by the storage system, whether the average compression rate is above a threshold;
if the average compression rate is above the threshold, compress data associated with the I/O operations; and
if the average compression rate is not above the threshold, not compress data associated with the I/O operations.

9. The computer program product of claim 8, wherein the average compression rate represents an average of the compression rate measured by the storage system for a last N intervals.

10. The computer program product of claim 8, wherein the storage system is a block-level storage system.

11. The computer program product of claim 8, wherein determining the compression rate comprises analyzing compressibility of data associated with the I/O operations for a selected period of time.

12. The computer program product of claim 8, wherein determining the compression rate comprises analyzing compressibility of data associated with the I/O operations for a selected number of I/O operations.

13. The computer program product of claim 8, wherein the threshold is based on a storage-recommended compression rate.

14. The computer program product of claim 8, wherein the computer-usable program code is further configured to store the data associated with the I/O operations on the storage system.

15. A system for more efficiently utilizing data compression in block-level storage systems, the system comprising:
at least one processor;
at least one memory device coupled to the at least one processor and storing instructions for execution on the at least one processor, the instructions causing the at least one processor to:
receive, by a storage system, I/O operations from a host system;
determine, by the storage system at a selected interval, a compression rate of data associated with the I/O operations;
update, by the storage system, an average compression rate with the compression rate determined at the selected interval;
determine, by the storage system, whether the average compression rate is above a threshold;
if the average compression rate is above the threshold, compress data associated with the I/O operations; and
if the average compression rate is not above the threshold, not compress data associated with the I/O operations.

16. The system of claim 15, wherein the average compression rate represents an average of the compression rate measured by the storage system for a last N intervals.

17. The system of claim 15, wherein the storage system is a block-level storage system.

18. The system of claim 15, wherein determining the compression rate comprises analyzing compressibility of data associated with the I/O operations for a selected period of time.

19. The system of claim 15, wherein determining the compression rate comprises analyzing compressibility of data associated with the I/O operations for a selected number of I/O operations.

20. The system of claim 15, wherein the threshold is based on a storage-recommended compression rate.
